(19) United States
(12) Patent Application Publication
(10) Pub. No.: US 2026/0319047 A1
(43) Pub. Date: Oct. 15, 2026

(54) METHOD AND SYSTEM FOR SIMULTANEOUS MAPPING OF B0 AND B1+ INHOMOGENEITIES IN MRI

(71) Applicant: Siemens Healthineers AG, Forchheim (DE)

(72) Inventors: Tom Hilbert, Renens (CH); Patrick Liebig, Erlangen (DE); Gian Franco Piredda, Renens (CH); Thomas Yu, Renens (CH); Natalia Pato Montemayor, Renens (CH)

(21) Appl. No.: 19/646,837

(22) Filed: Apr. 14, 2026

(30) Foreign Application Priority Data
Apr. 14, 2025 (EP) 25170264

(51) Int. Cl. G01R 33/561; G01R 33/565

(52) U.S. Cl. CPC G01R 33/5616; G01R 33/5611; G01R 33/56563; G01R 33/5659

(57) ABSTRACT

An MRI method and system simultaneously mapping B₀ and B₁⁺ inhomogeneities includes MRI pulse sequence biological object imaging, including saturation TurboFLASH data acquisition sequences, satTFL, for absolute B₁⁺ mapping. The satTFL sequence includes temporally successive elements. A first element is a presaturation TurboFLASH element, a second element is a magnetization preparation element, a third element is a magnetization-prepared TurboFLASH element. The first element includes flip angle RF excitation pulse β, the first flip angle pulse, and associated presaturation TurboFLASH readout. The second element includes RF excitation pulse α, the third element includes flip angle RF excitation pulse γ, the second flip angle pulse, and associated magnetization-prepared TurboFLASH readout acquiring magnetization-prepared image S_{1,0}. The associated presaturation TurboFLASH readout includes echoes for ΔB₀ mapping, and acquiring for each presaturation image ΔB₀ mapping. ΔB₀ and B₁⁺ maps of the object are determined from the magnetization-prepared image S_{1,0} and the presaturation images and output.

### CROSS-REFERENCE TO RELATED APPLICATION

This application claims the priority, under 35 U.S.C. § 119, of European Patent Application EP 25170264.3, filed Apr. 14, 2025; the prior application is herewith incorporated by reference in its entirety.

### FIELD AND BACKGROUND OF THE INVENTION

The present invention falls within the field of Magnetic Resonance Imaging (MRI) and proposes a system and a method for simultaneous mapping of B₀ and B₁⁺ inhomogeneities in Magnetic Resonance Imaging (MRI).

### DESCRIPTION OF THE RELATED ART

Ultra-high field (UHF) MRI (i.e. MRI with magnetic field strength ≥7 T) provides enhanced signal-to-noise ratio (SNR) and resolution compared to lower field strengths MRI. However, at UHF, the increased Larmor frequency of the water protons makes the associated wavelength comparable to the size of the imaged specimen (particularly when imaging the brain), which results in interferences that enhance transmission (B₁⁺) field inhomogeneities, resulting in severe signal voids in the acquired images. In order to address that issue, several techniques have been developed to ensure homogeneous flip angle distributions at UHF, such as configuring subject-specific radiofrequency (RF) pulses with dynamic parallel transmission [1]. However, those pulses require additional online mapping of the main magnetic (B₀) and channel-wise B₁⁺ fields, which increases total scan time. While optimized techniques for local B₀ inhomogeneities (ΔB0) and B₁⁺ mapping exist, they are typically performed separately, increasing sensitivity to motion artifacts, scanner workload, and acquisition time.

It is therefore desired to find a solution for simultaneous, rapid, mapping of B₀ and B₁⁺ inhomogeneities for dynamic parallel transmission optimization, capable of reducing a need for additional scans, as well as to mitigate motion sensitivity, streamline workflows, and decrease overall acquisition times.

### SUMMARY OF THE INVENTION

It is accordingly an object of the invention to provide a method and a system for simultaneous mapping of B₀ and B₁⁺ inhomogeneities in MRI, which overcome the hereinafore-mentioned disadvantages of the heretofore-known methods and systems of this general type.

This objective is achieved by the measures taken in accordance with the independent claims. Further advantageous embodiments are proposed by the dependent claims.

With the foregoing and other objects in view there is provided, in accordance with the invention, a method for simultaneous mapping, notably three-dimensional (3D) mapping, of B₀ and B₁⁺ inhomogeneities, the method comprising:
performing, by an MRI system, an MRI pulse sequence configured for imaging a biological object, the MRI pulse sequence including a main data acquisition sequence for absolute B₁⁺ mapping, which is a saturation TurboFLASH data acquisition sequence, called hereafter satTFL sequence, wherein the satTFL sequence includes at least three temporally successive elements, namely:
   a first element that is a pre-saturation TurboFLASH element, followed by
   a second element that is a magnetization preparation element, followed by
   a third element that is a magnetization-prepared TurboFLASH element,
   wherein the first element includes a flip angle RF excitation pulse β, called hereafter the first flip angle pulse, and an associated pre-saturation TurboFLASH readout, the second element includes a RF excitation pulse α (i.e. a saturation pulse, preferentially a 90° saturation pulse), and the third element includes a flip angle RF excitation pulse γ, called hereafter the second flip angle pulse (preferentially, β=γ), and an associated magnetization-prepared TurboFLASH readout for acquiring a magnetization-prepared image S_{1,0} of the biological object for B₁⁺ mapping. Optionally, the satTFL sequence is a Sandwich sequence, i.e. a sequence wherein the first element is temporally separated from the third element by a time interval that is the minimum time interval required for carrying out or performing the second element, or otherwise the, the temporal gap between the first element and the second element is almost 0;
   the associated pre-saturation TurboFLASH readout includes an acquisition of multiple echoes (i.e. gradient echo (GRE) readouts) for ΔB0 mapping (ΔB0 representing the inhomogeneities of B₀), wherein, for each echo, a respective pre-saturation image (i.e. GRE image) is acquired, and wherein the acquired pre-saturation images are used for the ΔB0 mapping;
   a ΔB0 map and a B₁⁺ map of the biological object are determined (or calculated or generated or created) from the magnetization-prepared image S_{1,0} and the pre-saturation images; and
   the ΔB0 and B₁⁺ maps are outputted, e.g. on a display.

The present invention proposes thus to modify the satTFL sequence by adding the acquisition of multiple echoes for ΔB0 mapping in the pre-saturation TurboFLASH element, creating therefore a “modified” satTFL sequence also called hereafter CLUB sequence, wherein “CLUB” stands for “Combined caLcUlation of Biases”. In particular, the CLUB sequence becomes a CLUB-Sandwich sequence in the case the satTFL sequence modified according to the invention is a Sandwich sequence.

By “simultaneous mapping”, it has to be understood that the images (or contrasts) used for the mapping of B₀ and B₁⁺ inhomogeneities are acquired for a spatial location within the biological object during the very same CLUB sequence, directly one after the other.

With the objects of the invention in view, there is concomitantly provided an MRI system configured for carrying out the steps of the previously described method.

### DESCRIPTION OF EMBODIMENTS

The present invention proposes a simultaneous mapping, i.e. measurement, of B₀ and B₁⁺ by acquiring, within the so-called CLUB sequence, multiple echoes for B₀ mapping during the first element of the CLUB sequence, and a (classical) magnetization-preparation image S_{1,0} during the third element of the CLUB sequence. A particular case of the CLUB sequence according to the invention is the so-called CLUB-Sandwich sequence. The latter is notably characterized by the fact that the delay time (TD) between the end of the first element and the start of the second element is approximatively 0 s. At the end, the ΔB₀ and the B₁⁺ map represent respectively a map of inhomogeneities of the main magnetic field B₀ and a map of the inhomogeneities of the transmit RF field B₁⁺.

The present invention is particularly relevant in the case of UHF

MRI, wherein magnetic field inhomogeneities might result in stronger contrast variations in the MRI images of the biological object compared to contrast variations appearing in lower fields, wherein the contrast variations are not related to features of the tissue of the biological object, and are therefore prone to misinterpretation. In this context of UHF MRI, the knowledge or measurement of ΔB₀ and B₁⁺ inhomogeneities (via the ΔB₀ and B₁⁺ maps according to the invention) makes it possible to correct or to take into account the measured inhomogeneities when reconstructing an MRI image for the biological object. In order to further improve imaging a biological object in UHF MRI, the present invention proposes in particular to use parallel transmission acquisition, hereafter pTx, for imaging the biological object. In this case, the MRI pulse sequence previously described preferentially includes, preceding the CLUB sequence, a (2D or resp. 3D) coil-cycled multi-channel data acquisition sequence for acquiring a (2D or resp. 3D) relative map of B₁⁺ for each acquisition coil or channel of the MRI system, wherein, for each channel, the method further includes calculating a respective channel-related B₁⁺ map by scaling the B₁⁺ map (which has been obtained from the magnetization-prepared image S_{1,0} and the pre-saturation images, and which is typically a (2D or resp. 3D) absolute map of B₁⁺ with a transmission fraction factor calculated voxel-wise from the (2D or resp. 3D) relative map of B₁⁺ obtained for the concerned channel. Indeed, each (2D or resp. 3D) relative map shows or measures a relative transmission fraction, i.e. the fraction of the B₁⁺ magnetic field that is measured by the concerned acquisition coil of the MRI imaging system.

According to the present invention, the associated pre-saturation

TurboFLASH readout integrates multiple GRE readouts. Preferentially, the associated pre-saturation TurboFLASH readout includes an acquisition of three, or of at least two, echoes (i.e. GRE images) for the ΔB₀ mapping. The echoes are preferentially monopolar echoes or bipolar echoes. In particular, the ΔB₀ map is then reconstructed (or calculated or determined) from the phases of the pre-saturation images. Other known in the art methods for estimating the ΔB₀ map from the pre-saturation images might be used.

Preferentially, the B₁⁺ map is an absolute volumetric flip angle map obtained from a ratio of one of the pre-saturation images (e.g. the first (temporally acquired) pre-saturation image) and the magnetization-prepared image S_{1,0} using a lookup table generated from Bloch equations and extended phase graph (EPG) simulations to account for T1 relaxation effects. This technique is known in the art (see for instance Weigel et al. [2]) and does not require additional explanations here.

Preferentially, P dummy CLUB sequences are acquired prior to the CLUB sequence that is used for mapping simultaneously ΔB₀ and B₁⁺, wherein P≥1.

Preferentially, the MRI pulse sequence, notably its CLUB sequence, might be accelerated by using an undersampling technique, e.g. a parallel imaging or compressed sensing method, for generating the pre-saturation images and the magnetization-prepared image S_{1,0}, wherein the ΔB₀ and B₁⁺ maps are then determined from the generated images, which might be reconstructed using known in the art dedicated reconstruction methods, like deep-learning based methods, adapted to the used undersampling technique.

Other features which are considered as characteristic for the invention are set forth in the appended claims.

Although the invention is illustrated and described herein as embodied in a method and a system for simultaneous mapping of B₀ and B₁⁺ inhomogeneities in MRI, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is an illustration of an MRI pulse sequence diagram according to the invention;

FIG. 2 is a schematic block diagram of a system according to the invention;

FIG. 3 is a flowchart of a preferred embodiment of a method according to the invention; and

FIG. 4 is an illustration of a mapping of B₀ and B₁⁺ inhomogeneities according to the invention.

### DETAILED DESCRIPTION OF THE INVENTION

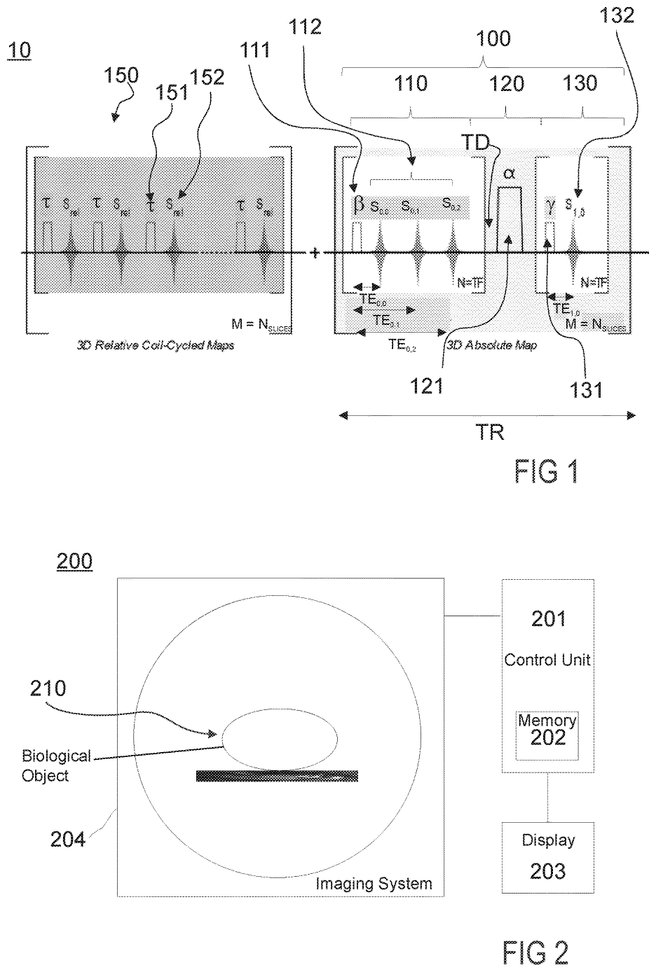

Referring now in detail to the figures of the drawings, with which further aspects of the present invention will be better understood and in which like numbers designate like objects, and first, particularly, to FIG. 1 thereof, there is seen a diagram of a preferred embodiment of an MRI pulse sequence 10 according to the invention. The illustrated MRI pulse sequence is a modified version of a previously developed MRI pulse sequence used for 3D B₁⁺ mapping, referred to as “Sandwich” [3], and which is itself a modified saturated TurboFLASH sequence, wherein pre-conditioned (or pre-saturation) and magnetization-prepared images “sandwich” a saturation pulse a in a single 3D sequence to further reduce T₁ sensitivity and acquisition time. The MRI pulse sequence 10 according to the invention includes at least a CLUB sequence 100, which is in the particular case illustrated in FIG. 1, a CLUB-Sandwich sequence, for absolute B₀ and B₁⁺ mapping, wherein the CLUB sequence 100 includes at least three temporally successive elements, namely:
a first element 110 that is a pre-saturation TurboFLASH element, followed by
a second element 120 that is a magnetization preparation element, followed by
a third element 130 that is a magnetization-prepared TurboFLASH element.

The first element 110 includes a flip angle RF excitation pulse β 111, called hereafter the first flip angle pulse β, followed by an associated pre-saturation TurboFLASH readout 112. The latter includes an acquisition of multiple echoes (i.e. of multiple MRI gradient echo signals) for ΔB₀ mapping. Preferentially, it includes an acquisition of three monopolar echoes, or otherwise the, of three pre-saturation images S_{0,0}, S_{0,1}, S_{0,2}, wherein each pre-saturation image S_{0,i} corresponds to the MRI gradient echo signal acquired at a time of echo TE_{0,i}, with i=0, . . . , 2. Of course, the pre-saturation TurboFLASH readout 112 may include an acquisition of more than 3 pre-saturation images, each at a respective different echo time. Typically, the first flip angle pulse β 112 is a low flip angle pulse characterized by a flip angle lower than 90°, for instance a 5° flip angle. According to the TurboFLASH technique, the first element 110 is characterized by a turbo factor TF, which defines the number N of times the first element 110 is successively repeated, i.e. TF=N. In particular, the time interval between the first flip angle pulse β of two directly successive first elements, called first echo spacing, is included between 3 ms and 8 ms.

The second element 120 includes an RF excitation (saturation) pulse a 121. It is preferentially configured for achieving a broad-band full-passage hyperbolic secant saturation pulse with angle of 90°.

The third element 130 includes a flip angle RF excitation pulse g 131, called hereafter the second flip angle pulse, followed by an associated magnetization-prepared TurboFLASH readout 132 for acquiring a magnetization-prepared image S_{1,0} (i.e. an MRI GRE signal) at a time of echo TE_{1,0}. According to FIG. 1, the third element includes a single echo acquisition for reconstructing the magnetization-prepared image S_{1,0}. However, there is no limitation with respect to the number of echoes that can be acquired during the third element. For instance, multiple echoes could be acquired during the magnetization-prepared TurboFLASH readout 132, wherein the magnetization-prepared image S_{1,0} could be reconstructed from one or several of the echoes (i.e. MRI echo signals) using for instance a weighted contrast calculation. Preferentially, in case of multiple echoes acquired in the third element 130, B₁⁺ is calculated from the first (temporally acquired) echo in the first element and the first (temporally acquired) echo in the third element 130 to avoid undesired T1-related effects. As mentioned above with respect to the TurboFLASH technique, the third element 130 is characterized by the turbo factor TF, which defines the number N of times the third element 130 is successively repeated. In FIG. 1, the square brackets within the CLUB sequence 100 indicates indeed a TurboFLASH repetition period for phase encoding. In particular, the time interval between the second flip angle pulse g of two directly successive third elements, called second echo spacing, is included between 1 ms and 4 ms.

As mentioned earlier, the CLUB sequence 100 illustrated in FIG. 1 is a CLUB-Sandwich sequence which is characterized by the fact that the delay time TD between the end of the first element and the start of the second element is approximatively 0 s, i.e. the second element starts (almost) directly at the end of the last pre-saturation TurboFLASH readout 112 of the first element. Preferentially, the first flip angle and the second flip angle are equal, i.e. b=g. In particular, N is typically included between 24 and 38, with N=32 preferentially.

FIG. 1 illustrates the CLUB sequence 100 for a single repetition time TR. A series of the CLUB sequences 100 according to the invention might be repeated for imaging a slice of the biological object, wherein the CLUB sequences 100 of the series are separated from each other by the repetition time TR of typically several hundreds of milliseconds, such series being for instance repeated M times by the MRI system for imaging a number N_{SLICES} of slices of the biological object, with N_{SLICES}=M. Of course, the MRI pulse sequence 10, notably the CLUB sequence 100, further includes additionally known in the art appropriate spatial encoding (namely frequency and phase encoding) by using magnetic field gradients for imaging each voxel of each slice of the biological object. In particular, the MRI system may run the MRI pulse sequence 10 with 2D or 3D spatial encoding for outputting respectively 2D or 3D ΔB₀ and B₁⁺ maps. In particular, the spatial encoding includes a linear phase encoding. Optionally, each phase-encoding step and RF pulse might be followed by a RF spoiling.

In particular, notably in the case of UHF MRI, the present invention further proposes to reduce the additional time required for data acquisition used for ΔB₀ and B₁⁺ mapping by accelerating MRI data acquisition as illustrated in FIG. 1. Indeed, the MRI pulse sequence 10 according to the invention may additionally include a coil-cycled multi-channel data acquisition sequence 150 (for instance a 3D sequence 150 as illustrated in FIG. 1) configured for acquiring (3D) relative maps of the biological object. The (3D) coil-cycled multi-channel data acquisition sequence 150 is performed by the MRI system according to the invention before the CLUB sequence 100. Optionally, notably in addition to the (3D) coil-cycled multi-channel data acquisition sequence 150, the MRI pulse sequence 10 may include one or several dummy scans (not shown) performed by the MRI system prior to the CLUB sequence 100 that is used for mapping of ΔB₀ and absolute B₁⁺ simultaneously. Each dummy scan is an absolute CLUB sequence 100 performed by the MRI system, but for which no MRI signal is collected and processed. The dummy scans typically take place between the (3D) coil-cycled multi-channel data acquisition sequence 150 and the CLUB sequence 100 illustrated in FIG. 1. As for the CLUB sequence 100, the (3D) coil-cycled multi-channel data acquisition sequence 150 is shown in FIG. 1 for a single repetition time. As known in the art, a series of the sequences 150 might be used for imaging a slice, and such series might be repeated M times by the MRI system for imaging the number N_{SLICES} of slices of the biological object, with N_{SLICES}=M. Afterwards, the dummy scans, e.g. two 3D dummy scans in case of 3D spatial encoding, are performed by the MRI system 200 before starting the repetition of the series of CLUB sequences 100 for acquiring the images required for imaging the M slices of the biological object.

The (3D) coil-cycled multi-channel data acquisition sequence 150 includes, for each MRI acquisition coil or channel of the MRI system, a flip angle RF excitation pulse τ 151, called hereafter the third flip angle pulse, followed by a channel-related MRI readout 152 for acquiring a relative image Sᵣₑₗ (i.e. an MRI echo signal for reconstruction of (3D) relative coil-cycled maps) for that channel or coil, wherein the relative image Sᵣₑₗ shows the relative transmission fraction of the B₁⁺ field that is acquired by the channel or coil. Preferentially, the flip angle of the third flip angle pulse is equal to the flip angle of the first flip angle pulse, for instance β=γ=τ.

FIG. 2 illustrates very schematically an MRI system 200 according to the invention that is configured for performing the simultaneous mapping of B₀ and B₁⁺ inhomogeneities. It includes for instance:
an imaging system 204, e.g. an MRI scanner, for imaging a biological object 210, the imaging system 204 being configured for performing an MRI pulse sequence 10 and for acquiring an MRI signal resulting from the MRI pulse sequence 10;
a control unit 201, typically including a processor and a memory 202, the control unit 201 being configured for controlling the imaging system 204 for performing the MRI pulse sequence 10, and for processing the acquired MRI signal in order to generate or reconstruct ΔB₀ and B₁⁺ maps; and
one or several displays 203 for displaying the ΔB₀ and B₁⁺ maps reconstructed from the MRI signal.

Preferentially, the MRI system 200 includes multi-channel phased array coils for parallel transmit imaging of the biological object 210. This enables the MRI system 200 to acquire the (3D) relative coil-cycled maps for estimating the inhomogeneities of B₁⁺.cc

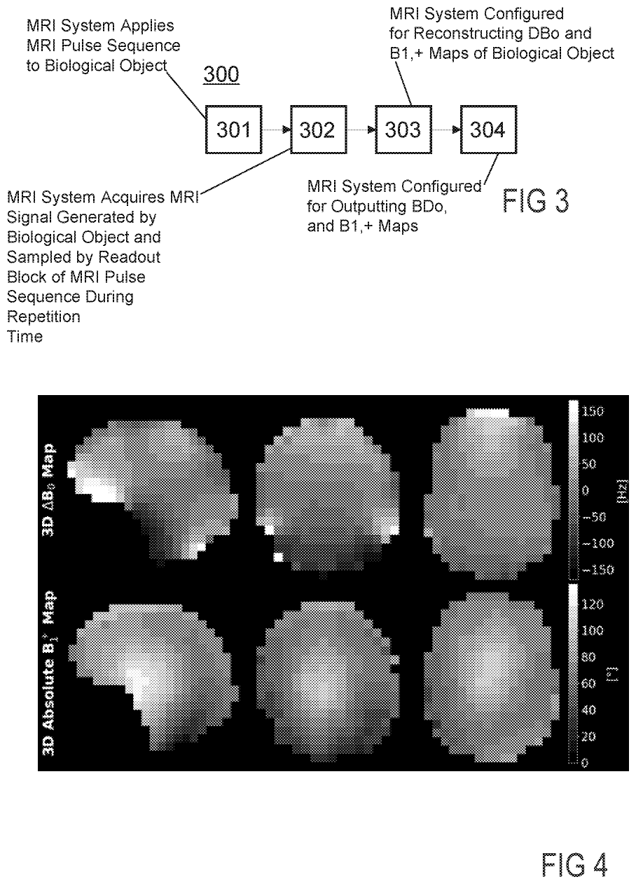

In connection with FIG. 3, the steps of a preferred embodiment of the method 300 according to the invention for simultaneously mapping B₀ and B₁⁺ inhomogeneities will be described in more detail hereafter.

At step 301, the MRI system 200 applies the MRI pulse sequence 10 according to the invention to the biological object 210. For instance, it may apply the MRI pulse sequence 10 illustrated in FIG. 1. Typically, the MRI pulse sequence 10 is stored in a memory of the MRI system 200, and its control unit 201 controls the imaging system 204 according to the MRI pulse sequence 10 for performing the simultaneously mapping of B₀ and B₁⁺ inhomogeneities.

At step 302, an MRI signal generated by the biological object 210 and sampled by the readout blocks of the MRI pulse sequence 10 is acquired by the MRI system 200 during each repetition time TR. Typically, the control unit 201 acquires the MRI signal via the imaging system 204, e.g. the scanner of an MRI apparatus. According to the present invention, the MRI signal includes multiple gradient echoes acquired during each pre-saturation TurboFLASH readout 110, wherein for each echo, the MRI system constructs or generates a pre-saturation image of the biological object 210. Each pre-saturation image includes voxel-wise information about B₀ that has been acquired from the echo. The MRI signal further includes another MRI echo signal acquired during each magnetization-prepared TurboFLASH readout and used by the MRI system for constructing a magnetization-prepared image S_{1,0} of the biological object 210. Each image S_{1,0} includes voxel-wise information about B₁⁺ that has been acquired from the generated MRI echo signal. Optionally, the MRI signal may include a channel-related MRI echo signal acquired during each channel-related MRI readout 152 for constructing a (2D or 3D) relative map of B₁⁺ magnetic field for the biological object 210 for the concerned channel.

At step 303, the MRI system 200, for instance its processing unit 201, is configured for reconstructing, from the magnetization-prepared image S_{1,0} and the pre-saturation images acquired during a same CLUB sequence 100, a ΔB₀ map and an absolute B₁⁺ map of the biological object 210, wherein ΔB₀ represents a map of inhomogeneities of the main magnetic field B₀ with respect to the biological object 210.

In particular, the processing unit 201 may estimate or determine the ΔB₀ map from the phases of S_{0,0}, S_{0,1}, and S_{0,2} by unwrapping the latter with a rapid open source minimum spanning tree algorithm (ROMEO) [4], and correcting offsets with multi-channel phase combination (MCPC-3D-S) [5]. Then, the processing unit 201 might be configured for applying a linear regression fit of the phases against the echo time to estimate or determine the ΔB₀ map as described in the paper of Windischberger et al. [6]. Of course, other known in the art techniques might be used for determining the ΔB₀ map from the pre-saturation images.

In particular, the processing unit 201 may estimate or determine the absolute B₁⁺ map from the ratio of one of the pre-saturation images, e.g. the pre-saturation image S_{0,1} obtained for the first echo, and the magnetization-prepared (S_{1,0}) image using a lookup table generated from Bloch equations and extended phase graph (EPG) [2] simulations to account for T1 relaxation effects. Preferentially, the processing unit 201 might be configured for calculating individual channel-wise B₁⁺ map by scaling, for each channel (or acquisition coil) of the MRI system 200, the absolute B₁⁺ map with the transmission fraction provided by the relative image Sᵣₑₗ of the coil-cycled multi-channel data acquisition sequence 150 obtained for the channel.

At step 304, the MRI system 200, for instance its processing unit 201, is configured for outputting the ΔB₀ and B₁⁺ maps. For instance, the MRI system 200 may display the maps on the display 203, or may use the maps for further processing, like optimizing the pTx of the MRI system 200.

In a preferred embodiment, the MRI pulse sequence 10 is characterized by the following imaging parameters: a first flip angle (b) and a second flip angle (g) both of 5°, a TF of N=32, echo times TE_{0,0}=0.69 ms, TE_{0,1}=2.26 ms, TE_{0,2}=3.83 ms, and a first echo spacing of 5.52 ms, a second echo spacing of 2.38 ms, a time of repetition TR of 1000 ms, two dummy TR periods, and an acquisition time of approximately 41 s. Preferentially, the third flip angle (t) is also 5°. FIG. 4 illustrates, from the left to the right, a sagittal, coronal, and axial view of an in vivo ΔB₀ map (top) and absolute B₁⁺ map (bottom) obtained for a brain. These maps were generated with the presently described CLUB-Sandwich sequence illustrated in FIG. 1, when using a nonselective broad-band full-passage hyperbolic secant saturation pulse, a linear phase-encoding, a RF spoiling, and the above-mentioned imaging parameters. According to the present invention, the MRI pulse sequence 10, in particular the CLUB sequence 100, might be configured for 2D or 3D imaging or mapping of the ΔB₀ and (absolute or relative) B₁⁺ map.

To conclude, the present invention proposes a simultaneous mapping of a biological object 210, like a brain, based on the use of a TurboFLASH readout wherein multiple GRE readouts have been integrated in the pre-saturation segment (i.e. in the first element 110) of the acquisition (i.e. of the CLUB sequence 100). This technique enables a reduction of the preparation time required for the configuration of pTx pulses used in UHF imaging. Additionally, the simultaneous mapping reduces the number of acquisitions and the challenges it implies (interscan motion and acquisition time). Finally, the maps obtained according to the present invention further enable retrospectively correcting MRI images of the biological object and/or optimization of the pTx.

### LIST OF CITATIONS

[1] Herrler J, Liebig P, Gumbrecht R, et al. Fast online-customized (FOCUS) parallel transmission pulses: A combination of universal pulses and individual optimization. Magn Reson Med. 2021; 85 (6): 3140-3153. doi:10.1002/mrm.28643.
[2] Weigel M. Extended phase graphs: Dephasing, RF pulses, and echoes-pure and simple. J Magn. Reason. Imaging. 2015; 41 (2): 266-295. doi:10.1002/jmri.24619.
[3] Kent JL, Dragonu I, Valkoviĉ L, Hess AT. Rapid 3D absolute B1+ mapping using a sandwiched train presaturated TurboFLASH sequence at 7 T for the brain and heart. Magn Reson Med. 2023; 89 (3): 964-976. doi:10.1002/mrm.29497
[4] Dymerska B, Eckstein K, Bachrata B, et al. Phase unwrapping with a rapid opensource
minimum spanning tree algorithm (ROMEO). Magn Reson Med. 2021; 85 (4): 2294-2308. doi:10.1002/mrm.28563
   [5] Eckstein K, Dymerska B, Bachrata B, et al. Computationally Efficient Combination of Multi-channel Phase Data From Multi-echo Acquisitions (ASPIRE). Magn Reson Med. 2018; 79 (6): 2996-3006. doi:10.1002/mrm.26963
   [6] Windischberger C, Robinson S, Rauscher A, Barth M, Moser E. Robust field map generation using a triple-echo acquisition. J Magn Reson Imaging. 2004; 20 (4): 730-734. doi:10.1002/jmri.20158 [Weigel 2015] Weigel M. Extended phase graphs: Dephasing, RF pulses, and echoes—pure and simple. J Magn Reson Imaging. 2015; 41 (2): 266-295. doi:10.1002/jmri.24619

1. An MRI method for simultaneous mapping of B₀ and B₁⁺ inhomogeneities, the MRI method comprising:
performing, by an MRI system, an MRI pulse sequence configured for imaging a biological object, the MRI pulse sequence including a saturation TurboFLASH data acquisition sequence, referred to hereinafter as satTFL, for absolute B₁⁺ mapping, the satTFL sequence including at least three temporally successive elements, namely:
a first element being a pre-saturation TurboFLASH element, followed by
a second element being a magnetization preparation element, followed by
a third element being a magnetization-prepared TurboFLASH element;
the first element including a flip angle RF excitation pulse β, referred to hereinafter as a first flip angle pulse, and an associated pre-saturation TurboFLASH readout, the second element including an RF excitation pulse α, and the third element including a flip angle RF excitation pulse γ, referred to hereinafter as a second flip angle pulse, and an associated magnetization-prepared TurboFLASH readout for acquiring a magnetization-prepared image S_{1,0};
the associated pre-saturation TurboFLASH readout including an acquisition of multiple echoes for ΔB₀ mapping, for each echo, a respective pre-saturation image for ΔB₀ mapping being acquired, resulting in a modified satTFL sequence referred to hereinafter as a “CLUB” sequence;
determining a ΔB₀ map and a B₁⁺ map of the biological object from the magnetization-prepared image S_{1,0} and the pre-saturation images; and
outputting the ΔB₀ and B₁⁺ maps.

2. The MRI method according to claim 1, which further comprises:
using parallel transmission acquisition, referred to hereinafter as pTx, for imaging the biological object, the MRI pulse sequence including, preceding the CLUB sequence, a coil-cycled multi-channel data acquisition sequence for acquiring a relative image for each acquisition coil or channel of the MRI system; and
for each channel, calculating a respective channel-related B₁⁺ map by scaling the B₁⁺ map with a transmission fraction factor calculated voxel-wise from the relative image obtained for the concerned channel.

3. The MRI method according to claim 1, which further comprises providing the multiple echoes as three monopolar echoes.

4. The MRI method according to claim 1, which further comprises determining or calculating the ΔB₀ map from phases of the pre-saturation images.

5. The MRI method according to claim 2, which further comprises providing the B₁⁺ map as an absolute volumetric flip angle map obtained from a ratio of one of the pre-saturation images and the magnetization-prepared image S_{1,0} using a lookup table generated from Bloch equations and extended phase graph simulations to account for T1 relaxation effects.

6. The MRI method according to claim 1, which further comprises acquiring P dummy CLUB sequences prior to the CLUB sequence being used for mapping simultaneously ΔB₀ and B₁⁺, wherein P is a strictly positive integer.

7. The MRI method according to claim 1, which further comprises accelerating the MRI pulse sequence by using an undersampling technique for generating the pre-saturation images and the magnetization-prepared image S_{1,0}, and determining the ΔB₀ and B₁⁺ maps from the generated images.

8. The MRI method according to claim 1, which further comprises running the MRI pulse sequence with respective 2D or 3D spatial encoding for outputting respective 2D or 3D ΔB₀ and B₁⁺ maps.

9. An MRI system configured for carrying out steps of the MRI method according to the claim 1.

10. The MRI system according to claim 9, which further comprises multi-channel phased array coils for parallel transmit imaging of the biological object.
